(19) United States
(12) Patent Application Publication
(10) Pub. No.: US 2004/0055883 A1
(43) Pub. Date: Mar. 25, 2004

(54) Magnetron sputtering target for non-magnetic materials

(76) Inventor: Shinzo Onishi, Palm Harbor, FL (US)

Correspondence Address: Nancy A. Pappas, 15210 Amberly Drive #1826, Tampa, FL, 33647, US

(21) Appl. No.: 10/664,790

(22) Filed: Sep. 17, 2003

Related U.S. Application Data
(63) Continuation-in-part of application No. 10/090,948, filed on Mar. 2, 2002, now Pat. No. 6,623,610.

(51) Int. Cl. C23C 14/35

(52) U.S. Cl. 204/298.19; 204/298.09

(57) ABSTRACT

A target for physical vapor deposition (PVD) and methods for depositing nonmagnetic materials are described. Power is introduced into the chamber through the target to produce plasma. The planar magnetron system is chosen for its high deposition rates. Since the permanent magnets are behind the target in traditional system, the magnetic target interferes with the required magnetic fields on the target. To eliminate this problem, permanent magnets are arranged on the target surface. Strong magnetic fields on the target can now be maintained for high deposition rates. The permanent magnets may be covered by a relatively thin, suitable protective film or by a film of the same material as the target.

### CROSS-REFERENCE TO RELATED APPLICATION

This application is a Continuation-In-Part of Ser. No. 10/090,948, filed Mar. 2, 2002, now U.S. Pat. No. 6,623,610, issued Sep. 23, 2003 which is considered as being incorporated herein.

### FIELD OF THE INVENTION

This invention relates to physical vapor deposition (PVD) and methods for depositing non-magnetic materials with planar sputtering systems.

### BACKGROUND OF THE INVENTION

Sputtering is a method of physical vapor deposition (PVD) that involves the removal of material from a solid cathode by bombarding it with positive ions form the discharge of a rare gas such as argon (Ar). The cathode can be made of a metal or an insulator and in contrast to thermal evaporation techniques, complex compounds such as high-temperature superconductor (HTS) materials can be sputtered with less chemical composition change. Sputtering is often done in the presence of a reactive gas, such as oxygen or nitrogen, to control or modify the properties of the deposited film. The following are some of the advantages of the use of the sputtering method:

1. The process is considered environmentally benign when compared to other chemical processes.

2. There is a wide range of choice of deposition rates for optimization of growth conditions.

3. There is a capability of excellent control of oxygen or nitrogen levels in the dielectric films formed by the process.

4. Both oxide and non-oxide targets may be utilized.

5. There is a possibility of both oxide and non-oxide targets being used in the process, allowing for reactive sputtering to be performed.

6. Both single and multi co-sputtering processes are possible.

7. The formation of c-axis oriented layers is possible on amorphous substrates.

8. In addition, growth of not only c-axis but also a-axis oriented layers is possible on a single-crystalline substrate.

The sputtering deposition process provides high density nucleation, which has not only a c-axis but also an a-axis orientation on single crystalline substrates. This process is ideal for the first, or nucleation step; however, it fails to make a single crystal because of the difficulty in maintaining thermal equilibrium growth conditions at higher temperatures to grow a single crystal. This is described in S. Onishi, Y. Hirokawa, T. Shiosaki and A. Kawabata,; Chemical Vapor Deposition of Single-Crystalline ZnO Film with Smooth Surface on Intermediately Sputtered ZnO Thin Film on Sapphire; Jpn. J. Appl. Phys., V17, 1978, pp. 773-778.

The planar magnetron system is relatively simple and provides high deposition rates from a simple flat target. The conventional system has permanent magnets behind the target that provide strong magnetic fields on the target. The magnetic fields confine high-density plasma to the target. The plasma on the target enhances the deposition rate dramatically. If it is a magnetic target, however, magnetic properties bypass the magnetic fields. Hence, magnetic fields on the target will be greatly reduced. Magnetic materials cannot be deposited effectively with a conventional planar magnetron system.

Magnetron systems are excellent for Physical Vapor Deposition (PVD) systems as a material source to be deposited because deposition rates are high and excess electron bombardment of the substrate is reduced. This is discussed in Onishi, M. Eschwei, W- C. Wang,; Transparent and Highly Oriented ZnO Films Grown at Low Temperature by Sputtering with a Modified Sputter Gun; Appl. Phys. Lett., V38, 1981, pp. 419-421.

The planar magnetron generates magnetic fields through the target. The strong magnetic field on the target confines the high-density plasma causing target corrosion. The conventional target will become thinner as erosion advances and magnetic fields on the eroded areas become stronger. The erosion profiles become deeper narrow rings.

The stronger magnetic field accelerates erosion by creating a narrow and deeper channel. This effect leads to a shorter target life and affects the uniformity of the deposited film on the substrate. The target utilization rate is also lower. To partially solve this problem, costly rotating magnets are required. The rotating magnets act as a magnetic break. This not only requires a significantly high power motor, but excess heat generated on the target also becomes a problem.

### SUMMARY OF THE INVENTION

It is therefore an object of the invention to provide a novel magnetron sputtering target having magnets affixed to the substrate-facing surface of the target to provide magnetic effects with smaller magnets.

It is a further object of the invention to provide a magnetron sputtering target with magnets affixed to the substrate-facing surface rather than behind the target.

It is another object of the invention to provide a system to prevent corrosion of the magnets in the sputtering system.

It is yet a further object of the invention to provide a sputtering system containing stronger magnetic flux on the target.

It is another object of the invention to provide a more precise design of the magnetic circuits that influence the magnetic flux.

It is still a further object of the invention to provide an improved magnetic circuit design which eliminates the need for rotating magnetic fields and, thus providing a more uniform deposition.

### BRIEF DESCRIPTION OF THE DRAWINGS

FIG. 1 is a schematic view of the sputtering system containing the target system of the instant invention.

FIG. 2 is a prior art target assembly.

FIG. 3 is an additional prior art target assembly with rotating magnets.

FIG. 4 is a target diagram of the assembly of the instant invention.

FIG. 5 shows a typical coated permanent magnet.

FIG. 6 depicts one embodiment of the target assembly of the instant invention.

FIG. 7 shows another embodiment of the target assembly of the instant invention.

FIG. 8 is a typical micro-patterned magnet array as utilized in the instant invention.

### DETAILED DESCRIPTION OF THE PREFERRED EMBODIMENTS

In the instant invention, the permanent magnets are placed on the target rather than behind the target. The major erosion area is between the opposite polarity permanent magnets that are on the target. The permanent magnets erode very little, and they may also be coated with suitable materials to prevent cross-contamination within the system. In this configuration, permanent magnetic strips or rings form magnetic fields directly on the target, whereas in the conventional planar magnetron systems, the magnetic fields are formed through the target. By use of the magnetic circuit design of the instant invention, the thickness of the target is no longer limited by the magnetic field characteristics desired, and there is also improved magnetic distribution. In addition, the required permanent magnets are smaller and thus less expensive.

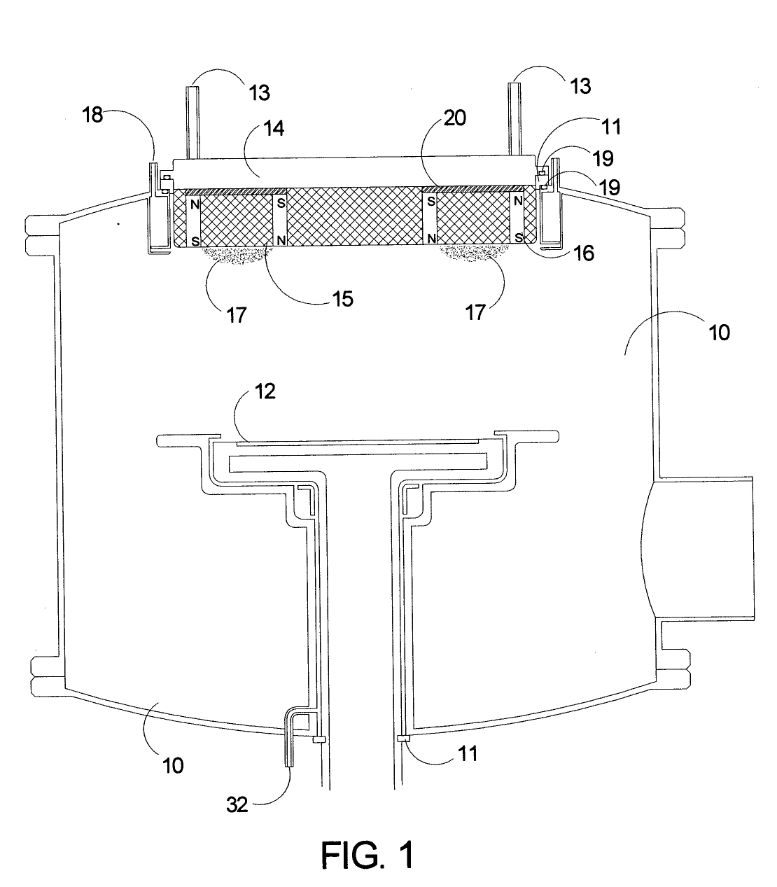

FIG. 1 shows a typical planar magnetron in a vacuum chamber incorporating the target design of the instant invention. Here, all permanent magnets have a polarization from top to bottom and the base plate provides a common base for the magnetic circuits set up by the permanent magnets. Space between the opposite permanent magnet polarities is filled by the target itself. Strong magnetic fields between opposite polarities trap and confine the high-density plasma. This high density plasma on the target enhances target erosion and as erosion advances, the magnetic fields tend to become weaker, resulting in wider erosion profiles. Since the magnetic circuits are directly exposed rather than transmitted through the thick target, smaller permanent magnets are used. The smaller magnets make it possible to achieve more efficient erosion patterns. This leads to a more uniform sputtering source without rotating the magnets or magnetic fields. Although the rotating magnetic assembly improves deposition uniformity, the rotation reduces the magnetic field on the target, generating more heat due to a magnetic break effect, which hinders ideal electrical feeding systems and triggers plasma instability which includes abnormal arc discharges.

FIG. 1 depicts a schematic view of the sputtering system of the instant invention. This system is comprised of a vacuum chamber 10, having a therein a target 15, a substrate 12, and a magnet 16 which is part of a magnetron array. Since sputtering is a method of physical vapor deposition that involves the removal of material from a solid cathode or target, such as target 15, this is effected by bombardment of target 15 with positive ions from the discharge of a rare gas such as argon (Ar), or any other suitable gas as known to those of ordinary skill in the art and is supplied via gas inlet 18. The target 15 may be made of a metal, an insulator or other suitable material, and is heated by ion bombardment or discharge energy in the preferred embodiments. The excess heat build-up must be removed by a water jacket 14 with continually circulating water through inlets/outlets 13. The water jacket 14 is capable of cooling without the use of high power motors due to the lack of the rotating magnets present in the prior art systems. The target assembly is built into the chamber by means of an insulating ring 11 and a vacuum seal 19.

The substrate 12, may be a wafer on which components are fabricated, but also other suitable substrates, as known to those of ordinary skill in the art may also be used. These include, but are not limited to, microelectronic wafer, optical elements and other surfaces requiring a coated surface.

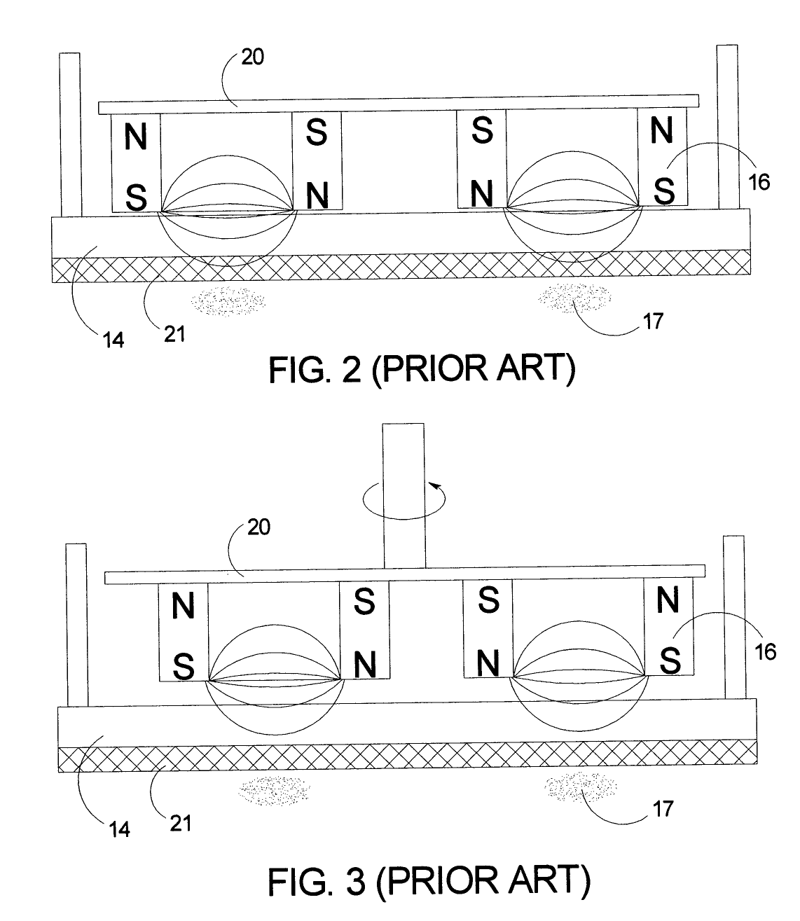

Conventional planar magnetron sputtering assemblies as known in the prior art are shown in FIGS. 2 and 3. The magnetic field is provided by permanent magnets 16 mounted on the magnetic base plate 20 behind the target. The field thus defined confines the high-density plasma 17. Locating the plasma on the target greatly enhances the deposition rate of the coating.

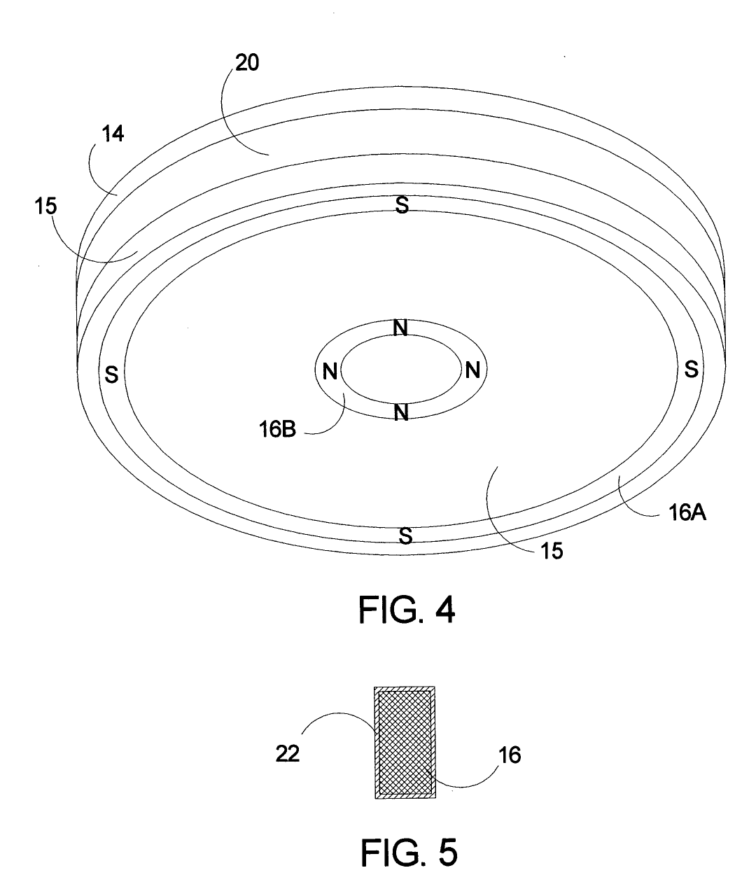

A preferred embodiment of the magnetic array of the instant invention is shown in FIG. 4. The target portion of the sputtering system consists of an array of permanent magnets fastened to the target surface facing the substrates at an appropriate distance from the substrates.

The magnets 16A and 16B which are exposed in the plasma may be coated with suitable magnetic and/or non-magnetic materials 22 by plating, or other suitable process, and are shown in FIG. 5. This practice is known to those of ordinary skill in the art and is considered conventional for corrosion prevention.

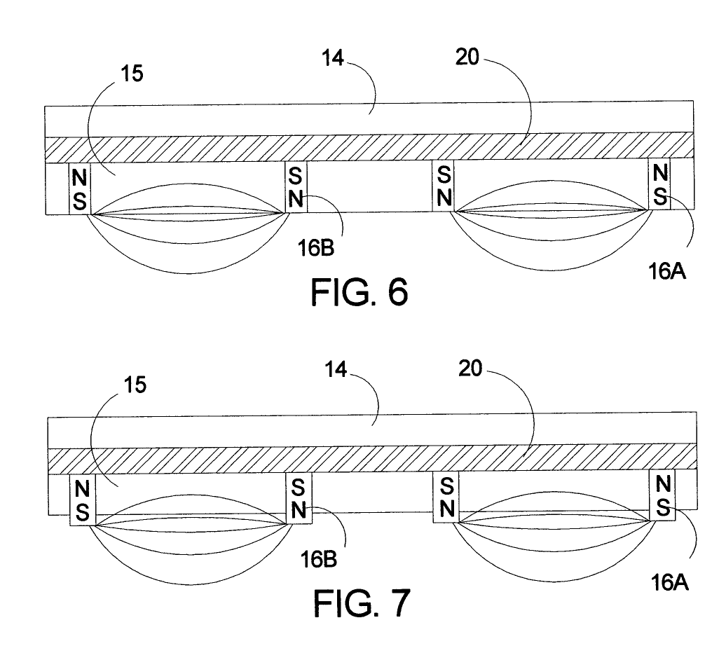

Two variations of target assemblies are shown in FIGS. 6 and 7. In the simplest application, two rings of magnets are attached to the magnetic base by the force of their own magnetic properties, as shown in FIG. 6. Here, the back of the target is bonded to a magnetic backing plate 20 proximal to the water jacket 14, for cooling purposes. Other attachment methods may be used, including bonding by a suitable material, a material, a mechanical means or any combination of methods to attach the magnets to the target. The embodiment of FIG. 7 shows the magnets partially embedded in the target 15.

The surface of the target 15 may be modified according to magnetic circuits, permanent magnets, gas composition and pressure, operating power and the spacing between the north 16B and south 16A magnets mounted on the surface of the target. FIG. 6 shows the target 15 with a flashed surface, which, when exposed to the plasma, enhances the reactive sputtering without building up of sputtered material around the gaps. Thus, the system can be operated without accumulating arc discharge courses.

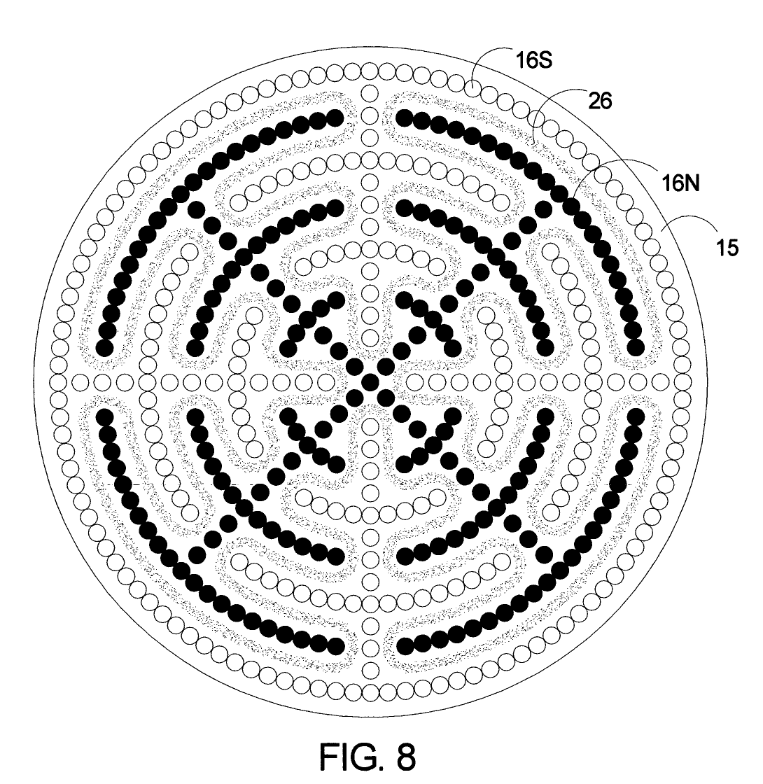

Performance of the target assembly of the instant invention can be maximized by use of a micro-patterned magnetic circuit as shown in FIG. 8. The small magnets are embedded or are in guiding trenches and thus form micro-patterns of magnetic field between north 16N and south 16S poles on the target 15. The plasma is confined in the magnetic field and micro-erosion patterns 26 are formed. Those erosion patterns are uniformly distributed so that the material supply will be uniform with short through sputtering.

The substrate is also capable of being moved closer to the target. In this way, multiple benefits, such as high deposition rate, minimum chamber contamination and better deposition uniformity are obtained. The semi-direct exposure of the permanent magnets provides the best uniformity of magnetic field over the whole target area.

The instant invention is an excellent system for the deposition of non-magnetic coatings on a wide variety of surfaces. These coatings include, but are not limited to, dielectric compounds, insulating layer compounds, metals, such as Al, Mg, Au, alloys, such as NiCr (non-magnetic), In—Sr ceramics, including those such as PZT, and other materials as known to those of ordinary skill in the art.

Modification and variation can be made to the disclosed embodiments of the instant invention without departing from the scope of the invention as described. Those skilled in the art will appreciate that the applications of the present invention herein are varied, and that the invention is described in the preferred embodiment. Accordingly, additions and modifications can be made without departing from the principles of the invention. Particularly with respect to the claims, it should be understood that changes may be made without departing from the essence of this invention. In this regard, it is intended that such changes would still fall within the scope of the present invention. Therefore, this invention is not limited to the particular embodiments disclosed, but is intended to cover modifications within the spirit and scope of the present invention as defined in the appended claims.

What is claimed is:

1. A magnetron sputtering system for deposition of non-magnetic materials comprising permanent magnets fastened to the magnetic target surface facing the substrates at an appropriate distance from the substrates.

2. The system of claim 1, wherein the magnets are coated with suitable materials such as the target material or a non-contaminating material with respect to the deposited coating so that no contaminating materials are deposited on the substrate due to magnet erosion.

3. The system of claim 1, wherein the permanent magnets are directly exposed to the plasma rather than through the thick target.

4. The system of claim 1 wherein, the permanent magnets are held on the backing plate by a method selected from the group consisting of magnetic force, adhesive bonding, mechanical means or by a combination of these means.

5. The system of claim 1, wherein the thickness of the target is not limited.

6. The system of claim 1, wherein the surface of the target is a non-planar, machined surface that may be used for a variety of applications.

7. The system of claim 1, wherein there is additionally a water jacket.

8. The system of claim 1, wherein there are no rotating magnets.

9. The system of claim 1, wherein the magnets provide a stable plasma with no abnormal arc discharge and deposition uniformity due to their location of the surface of the target.

10. The system of claim 1, wherein the plasma feeding and cooling are effected without the use of a high power motor.

11. The system of claim 1, wherein the shape of the magnets provides magnetic flux over the entire erosion area.

12. The system of claim 1, wherein the target is laminated to a magnetic backing plate.
